(19) United States
(12) Patent Application Publication
(10) Pub. No.: US 2026/0133263 A1
(43) Pub. Date: May 14, 2026

(54) METHOD FOR CALIBRATING AN ANGULAR POSITION SENSOR

(71) Applicant: HELLA GMBH & CO. KGAA, Lippstadt (DE)

(72) Inventors: Marius Alexandru Constantin, Sacalaz (RO); Philipp Molkenthin, Stuhr (DE)

(21) Appl. No.: 19/385,850

(22) Filed: Nov. 11, 2025

(30) Foreign Application Priority Data
Nov. 12, 2024 (EP) 24212392.5

(51) Int. Cl. G01R 33/00; G01B 7/30; H02K 7/116; H02K 11/215

(52) U.S. Cl. CPC G01R 33/0035; G01B 7/30; H02K 7/116; H02K 11/215

(57) ABSTRACT

The invention relates to a method for calibrating an angular position sensor, e.g. a contactless inductive position sensor or a Hall sensor, arranged at an output shaft of an actuator. The actuator may be provided for a vehicle application, e. g. for engine control, steering control, cooling control etc. Angular positions of the output shaft obtained by the angular position sensor and real angular positions of the output shaft calculated using angular positions of a motor shaft are compared.

### CROSS-REFERENCE TO RELATED APPLICATIONS

The present application claims the benefit of European Patent Application 24212392.5, filed Nov. 12, 2024, the disclosure of which is incorporated by reference.

### BACKGROUND OF THE INVENTION

The invention is related to a method for calibrating an angular position sensor, especially a contactless inductive position sensor (CIPOS) or a Hall sensor, of an actuator, preferably for a vehicle application, e. g. for engine control, steering control, cooling control etc. Besides, the invention is related to a corresponding computer program product and corresponding electronic control unit configured to execute respective method. Further, the invention is related to a corresponding actuator with an angular position sensor and a respective electronic control unit configured for calibrating the angular position sensor.

Actuators for vehicle applications usually require internal angular position sensors, e. g. a contactless inductive position sensor (CIPOS), a Hall sensor or the like, at the output shaft for proper operation. One possible application is cooling control for components in electric cars, e.g. battery etc.

Actuators may be driven by a brushless motor and need to know the motor position very well in order to define the correct commutation timing. A Brushless motor may use either a “sensorless drive solution” and BEMF signal or a “sensored drive solution” (using a motor position sensor, like Hall switches, Hall sensor, another CIPOS sensor or the like) to determine the motor position.

The actuator internal angular position sensors at the output shaft of the actuators will be usually calibrated after actuator assembly.

For this aim, external angular position sensors with considerably high precision are usually used to calibrate the actuator internal angular position sensors at the output shaft of the actuators.

Drawbacks are however that production time and effort of actuators are increased due to this calibration process.

Synchronization of signals between the external angular position sensors and the actuator internal angular position sensor at the output shaft is challenging. Also, the output shaft of the actuator must be connected free of backlash to an external angular position sensor as any backlash compromises calibration result.

The resolution of the actuator internal angular position sensor at the output shaft is also limited due to constraints in the communication interface and thus limiting the benefit of the calibration process.

### SUMMARY OF THE INVENTION

The aim of the present invention is to at least partially overcome at least one of the above-mentioned disadvantages. Preferably, the aim of the present invention is to provide an improved method for calibrating an angular position sensor, which may be executed with reduced time and effort, which requires reduced computational and physical resources and which provides improved results of the angular position sensor after calibrating process. Besides, the aim of the present invention is to provide a corresponding computer program product and corresponding electronic control unit configured to execute the respective method. Further, the aim of the present invention is to provide a corresponding actuator with an angular position sensor and a respective electronic control unit configured for calibrating the angular position sensor.

Embodiments of the invention provides: a method for calibrating an angular position sensor, e. g. a contactless inductive position sensor (CIPOS) or a Hall sensor, especially arranged at an output shaft of an actuator, wherein the actuator is preferably provided for a vehicle application, e. g. for engine control, steering control, cooling control etc.

The actuator may comprise: an electrical motor, especially a brushless dc motor, configured to drive a motor shaft and to provide an incremental sensor using a motor back EMF signal; and a gear mechanism configured to provide a gear ratio between the motor shaft and the output shaft of the actuator.

The angular position sensor may be mounted at an output shaft of an actuator or in other gear stages of the gear mechanism. There may be actuators, where the exact position of the output shaft may be needed. There may be also actuators, where other gear stages and their positions may be of interest. The output shaft within the meaning of the invention may therefore be a particular shaft in one of the stages in the gear mechanism.

The method may comprise: operating the angular position sensor to obtain angular positions of the output shaft; operating the electrical motor as the incremental sensor to determine angular positions and/or a number of revolutions of the motor shaft (which is especially equal to the number of electrical rotations and/or rollovers of the electrical motor); calculating real angular positions of the output shaft using the angular positions and/or the number of revolutions of the motor shaft; comparing the angular positions of the output shaft obtained by the angular position sensor and the real angular positions of the output shaft calculated using the angular positions and/or the number of revolutions of the motor shaft; and calibrating the angular position sensor in dependence on the comparing.

Back EMF (or back electromotive force) is a voltage induced through the magnetic field in the motor.

The electrical motor used as an incremental sensor may count the number of electrical rotations and/or rollovers of the electrical motor, especially of revolutions of the motor shaft.

The idea of the invention is to use the signal of motor commutation (and preferably the fixed gear ratio of the gear mechanism) to calibrate the actuator internal position sensor at the output shaft of the actuator. Preferably this method may be executed completely actuator internally and without an external position sensor.

Thus, a plurality of benefits may be achieved with the help of this method: production time and effort of the actuator may be drastically reduced due to this calibration process; only reduced computational power and resources are necessary; only reduced hardware, without external position sensor, is necessary; and improved calibration results may be achieved, etc.

Preferably, the gear ratio of the gear mechanism may be considered to calibrate the angular position sensor, especially by calculating the real angular positions of the output shaft using the angular positions and/or the number of revolutions of the motor shaft. The invention recognizes that by knowing the exact angular position and/or the number of revolutions of the motor shaft and further knowing the gear ratio of the gear mechanism between the motor shaft and an output shaft of the actuator, the real angular position of the output shaft may be calculated and used to verify the current sensor value.

Further, it may be advantageous, that the angular position sensor may be operating to obtain an angular position of the output shaft (or with other words a sensor value) every predetermined time period, for example every 3 ms, during an operation of the electrical motor as the incremental sensor. Thus, a plurality of sensor values (or with other words plurality of angular positions of the output shaft) may be achieved which may be used in the improved calibrating process.

Furthermore, it may be advantageous, that the angular position sensor is operating to obtain a plurality of angular positions of the output shaft (or with other words a plurality of sensor values) for at least two (or more) electrical rotations and/or rollovers of the electrical motor, especially for at least two (or more) revolutions of the motor shaft. Two rollovers of the electrical motor may be preferably needed because of the gear ration. It may also be preferably to rotate more often for this aim.

Accordingly, it may be advantageous, that operating the electrical motor, especially with a constant speed, e. g. 300 rad/s, as the incremental sensor may be executed for at least two electrical rotations and/or rollovers of the electrical motor, especially for at least two (ore more) revolutions of the motor shaft.

This may be beneficial to be able to detect a maximal angular position (or a maximal sensor value) and a minimal angular position (or a minimal sensor value) of the output shaft and beyond that to calculate a resolution of the angular position sensor.

With other words, it may be beneficial to be able to obtain a whole set of sensor values between a minimal sensor value and a maximal sensor value. Moreover, a resolution of the angular position sensor may be determined in dependence on a minimal sensor value and a maximal sensor value.

At least two (ore more) revolutions of the motor shaft may be needed: first rollover may be needed to detect a zero-position if the output shaft and to get the mechanics to a constant speed; second rollover may be needed to collect timely matching data of motor-spins and sensor values, which may be preferably used for the calibration.

Thus, the angular position of the output shaft may be precisely calculated using the motor shaft position. The calculated angular position of the output shaft may then be compared to the current sensor value (that is the current angular position of the output shaft according to the actuator internal angular position sensor at the output shaft). If some deviations occur, the current sensor value may be corrected in the improved calibrating process.

Further, the method may comprise at least one of the following: storing the angular positions of the output shaft obtained by the angular position sensor; storing the real angular positions of the output shaft calculated using the angular positions of the motor shaft; calculating deviations between the angular positions of the output shaft obtained by the angular position sensor and the real angular positions of the output shaft calculated using the angular positions and/or the number of revolutions of the motor shaft; storing the deviations, especially in a memory unit of the actuator; and calibrating the incremental sensor using the deviations.

Thus, a table of detected sensor values of calculated angular positions and of deviations between them may then be provided. With the help of such a table, improved calibration results may be achieved.

Memory unit may be provided inside or outside of the actuator, e.g. via connector.

In one preferable embodiment, the method may comprise at least one of the following: spinning the electrical motor; checking sensor values of the angular position sensor every predetermined time period, for example every 3 ms, until a first rollover of the electrical motor; continuing to spin the motor; checking sensor values of the angular position sensor every predetermined time period, for example every 3 ms, until a second rollover of the electrical motor; calculating deviations between sensor values of the angular position sensor and corresponding calculated positions of the output shaft using the angular positions and/or the number of revolutions of the motor shaft; and calibrating the angular position sensor using the deviations.

Thus, one preferable way how to execute the method may be provided, in order to be able to calibrate the angular position sensor with improved resolution.

Advantageously, the method may be executed during a regular operation of the actuator. Thus, an improved actuator may be provided, which can serve for improved, reliable and safe vehicle applications.

Beneficially, the method may be executed in a recurring, periodic, event-specific way, for example each time the actuator is starting, and/or upon a request, for example of a user of the vehicle.

Embodiments of the invention further provides: a computer program product, comprising instructions, which, when the computer program is executed by a computer, cause the computer to carry out the method as described above. With the help of the computer program product, the same advantages may be achieved as described above.

Embodiments of the invention further provides: an electronic control unit, comprising a memory unit and a control unit, wherein in the memory unit a code is stored, wherein when the code is executed by the control unit, the method according to one of the preceding steps is executed. With the help of the electronic control unit, the same advantages may be achieved as described above. Preferably, the deviations may be stored in the memory unit, especially to be used for calibrating the angular position sensor.

Embodiments of the invention further provides: an actuator, preferably for a vehicle application, e. g. for engine control, steering control, cooling control etc., comprising an angular position sensor and an electronic control unit as described above configured for calibrating the angular position sensor. With the help of the actuator, the same advantages may be achieved as described above.

### BRIEF DESCRIPTION OF THE DRAWINGS

An embodiment of the invention is explained in more detail below with reference to the accompanying drawings. The following exemplary description includes:

FIG. 1 shows an exemplary actuator in an exploded view;

FIG. 2 shows an exemplary procedure for recording sensor values;

FIG. 3 shows an exemplary procedure for recording sensor values; and

FIG. 4 shows an exemplary table with sensor values and deviations.

### DETAILED DESCRIPTION OF THE CURRENT EMBODIMENTS

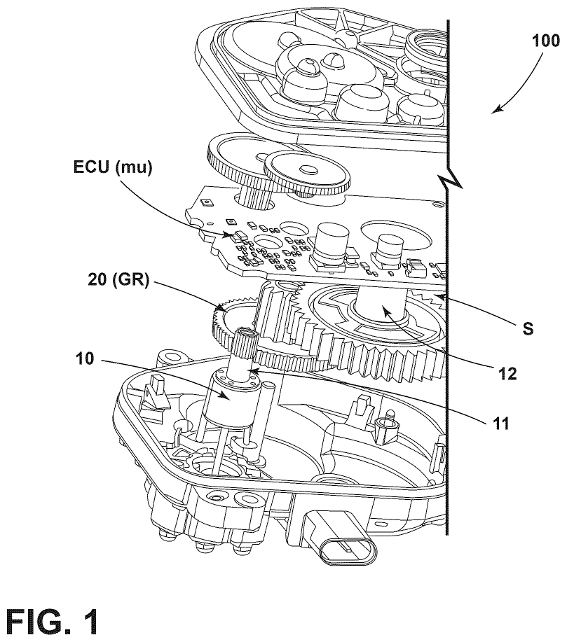

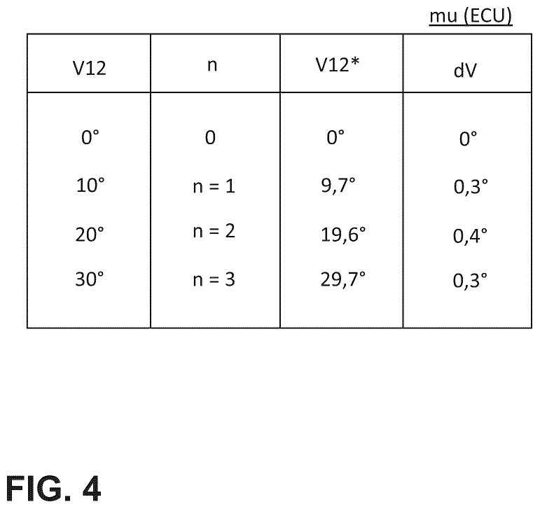

FIGS. 1 to 4 serve to explain the inventive idea.

In will be provided: a method for calibrating an angular position sensor S, e. g. a contactless inductive position sensor (CIPOS) or a Hall sensor or the like, e. g. arranged at an output shaft 12 of an actuator 100, wherein the actuator 100 is preferably provided for a vehicle application, e. g. for engine control, steering control, cooling control etc.

The actuator 100 may comprise following components: an electrical motor 10, especially a brushless dc motor, configured to drive a motor shaft 11 and to provide an incremental sensor using a motor back EMF signal; and a gear mechanism 20 configured to provide a gear ratio GR between the motor shaft 11 and the output shaft 12 of the actuator 100.

The angular position sensor S may be for example mounted at an output shaft 12 of an actuator 100 or in other gear stages of the gear mechanism 20. There may be actuators 100, where the exact position of the output shaft 12 may be needed. There may be also actuators 100, where other gear stages and their positions may be of interest. The output shaft 12 may be in general a shaft in a particular stage of the gear mechanism 20.

The method comprises the following actions/method steps: operating the angular position sensor S to obtain angular positions V12 of the output shaft 12 (for example as an angle between 0° and) 360°; operating the electrical motor 10 as the incremental sensor to determine angular positions V11 (for example as an angle between 0° and) 360° and/or a number n (for example 1, 2, 3 etc.) of revolutions of the motor shaft 11; calculating real angular positions V12* of the output shaft 12 using the angular positions V11 and/or the number n of revolutions of the motor shaft 11; comparing the angular positions V12 of the output shaft 12 obtained by the angular position sensor S and the real angular positions V12* of the output shaft 12 calculated using the angular positions V11 of the motor shaft 11; and calibrating the angular position sensor S in dependence on the comparing.

Back EMF (or back electromotive force) is a counter voltage induced through the magnetic field in the motor. In sensorless commutation, no separate sensors are used to detect the current rotor position; instead, the information is obtained indirectly by measuring electrical parameters on the coils. There are several methods available for this, such as detecting the rotor position via the counter voltage triggered in the coils of the stator, which is analyzed by an electronic control unit ECU.

The electrical motor 10 used as an incremental sensor may count the number n of electrical rotations and/or rollovers of the electrical motor 10, especially of revolutions of the motor shaft 11.

The method uses the signal of motor commutation (and preferably the fixed gear ratio of the gear mechanism 20) to calibrate the actuator internal position sensor at the output shaft 12 of the actuator 100. This may be executed completely actuator internally and without external position sensor.

Different benefits may be achieved with the help of this method: production time and effort of the actuator 100 may be drastically reduced due to this calibration process; computational time and effort may be drastically reduced; hardware components, such as external position sensor, may be omitted; improved calibration results may be provided, etc.

Preferably, the gear ratio GR of the gear mechanism 20 may be considered by calculating the real angular positions V12* of the output shaft 12 using the angular positions V11 and/or the number n of revolutions of the motor shaft 11.

The angular position V12* of the output shaft 12 (which may be understood as an angle between 0° and) 360° may be especially calculated as a function of a number n of revolutions of the motor shaft 11 and of a gear ration GR: V12*=f (n, GR).

The exact angular position V11 of the motor shaft 11 may be calculated dependently on the number n of revolutions of the motor shaft 11 and the resolution of the incremental sensor (provided by the electrical motor 10).

By knowing the exact angular position V11 and/or the number n of revolutions of the motor shaft 11 (using the electrical motor 10 as an incremental sensor) and the gear ratio GR of the gear mechanism 20 between the motor shaft 11 and an output shaft 12 of the actuator 100, the real angular position of the output shaft 12 may be calculated very precisely.

The angular position sensor S may be operating to obtain an angular position V12 of the output shaft 12 (or with other words one sensor value) every predetermined time period, for example every 3 ms, during an operation of the electrical motor 10 as the incremental sensor. Advantageously, the angular position sensor S may be operating to obtain a plurality of angular positions V12 of the output shaft 12 (or with other words a plurality of sensor values) for at least two electrical rotations and/or rollovers of the electrical motor 10, especially for at least two revolutions of the motor shaft 11.

Accordingly, it may be advantageous, that operating the electrical motor 10, especially with a constant speed, e. g. 300 rad/s, as the incremental sensor may be executed for at least two electrical rotations and/or rollovers of the electrical motor 10, especially for at least two revolutions of the motor shaft 11.

Thus, a maximal angular position (or a maximal sensor value) and a minimal angular position (or a minimal sensor value) of the output shaft 12 may be determined. Furthermore, a resolution of the angular position sensor S may be calculated.

In other words, it may be beneficial to be able to obtain a whole set of sensor values between a minimal sensor value and a maximal sensor value. Moreover, a resolution of the angular position sensor S may be determined in dependence on a minimal sensor value and a maximal sensor value.

Thus, the real angular position V12* of the output shaft 12 may be precisely calculated using motor shaft angular position V11 and the gear ration GR.

The calculated angular position of the output shaft 12 may then be compared to the current sensor value (that is the current angular position V12 of the output shaft 12 according to the actuator internal angular position sensor S at the output shaft 12).

If some deviations occur, the current sensor value may then be corrected in the proposed calibrating process.

Further, the method may comprise at least one of the following: storing the angular positions V12 of the output shaft 12 obtained by the angular position sensor S; storing the real angular positions V12* of the output shaft 12 calculated using the angular positions V11 of the motor shaft 11; calculating deviations dV between the angular positions V12 of the output shaft 12 obtained by the angular position sensor S and the real angular positions V12* of the output shaft 12 calculated using the angular positions V11 and/or the number n of revolutions of the motor shaft 11; storing the deviations dV, especially in a memory mu of the actuator 100; calibrating the incremental sensor S using the deviations dV.

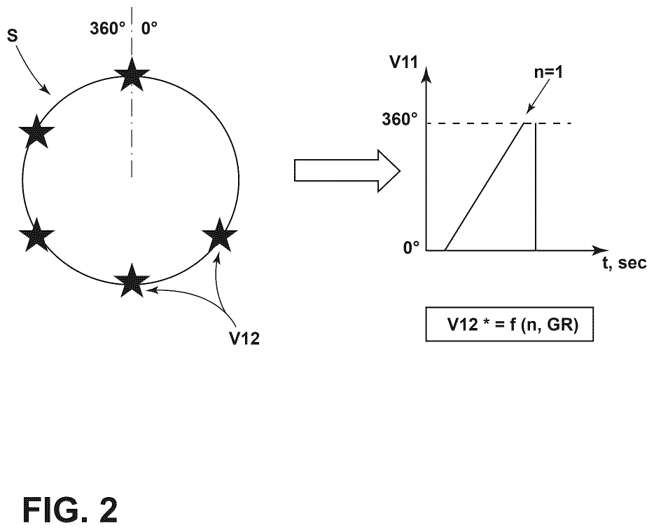

In one preferable embodiment, the method may comprise the following method steps, as FIG. 2 suggests: spinning the electrical motor 10; checking sensor values of the angular position sensor S every predetermined time period, for example every 3 ms, until a first rollover of the electrical motor 10.

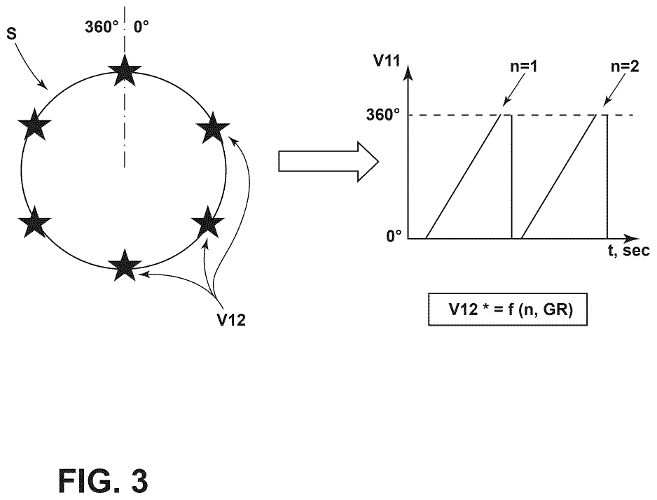

In this preferable embodiment, the method may comprise the following method steps, as FIG. 3 suggests: continuing to spin the motor 10; checking sensor values of the angular position sensor S every predetermined time period, for example every 3 ms, until a second rollover of the electrical motor 10.

After that, the method may comprise the following method steps in this preferable embodiment: calculating deviations dV between sensor values of the angular position sensor S and corresponding calculated positions of the output shaft 12 using the angular positions V11 and/or the number n of revolutions of the motor shaft 11; calibrating the angular position sensor S using the deviations dV.

Advantageously, the method may be executed during a regular operation of the actuator 100, beneficially in a recurring, periodic, event-specific way, for example each time the actuator 100 is starting, and/or upon a request, for example of a user of the vehicle.

A corresponding computer program product and a corresponding electronic control unit ECU represent also aspects of the present invention.

A corresponding actuator 100, preferably for a vehicle application, e. g. for engine control, steering control, cooling control etc. also represents an aspect of the present invention.

The above description of the figures describes the present invention solely by way of example. Of course, individual features of the embodiments can be freely combined with one another without departing from the scope of the invention, provided this is technically expedient.

List of reference symbols:

| | |
|---|---|
| 100 | actuator |
| 10 | electrical motor |
| 11 | motor shaft |
| 12 | output shaft |
| 20 | gear mechanism |
| S | angular position sensor |
| ECU | electronic control unit |
| mu | memory unit |
| GR | gear ration |
| n | number of electrical rotations and/or rollovers of the |
| | electrical motor, that is number of revolutions of the |
| | motor shaft (provided by the sensorless motor |
| | commutation) |
| V11 | angular positions of the motor shaft (provided by the |
| | sensorless motor commutation) |
| V12 | angular positions of the output shaft (measured by the |
| | angular position sensor), respective sensor values |
| V12* | real/calculated angular positions of the output shaft |
| | (calculated using the angular positions and/or the |
| | number of revolutions of the motor shaft and preferably |
| | the gear ration), respective comparative values |
| dV | deviations |

The above description is that of a current embodiment of the invention. Various alterations and changes can be made without departing from the spirit and broader aspects of the invention. This disclosure is presented for illustrative purposes and should not be interpreted as an exhaustive description of all embodiments of the invention or to limit the scope of the claims to the specific elements illustrated or described in connection with these embodiments. Any reference to elements in the singular, for example, using the articles “a,” “an,” “the,” or “said,” is not to be construed as limiting the element to the singular.

1. A method for calibrating an angular position sensor arranged at an output shaft of an actuator, wherein the actuator comprises an electrical motor configured to drive a motor shaft and to provide an incremental sensor using a motor back EMF signal, and a gear mechanism configured to provide a gear ratio between the motor shaft and the output shaft of the actuator, the method comprising:
operating the angular position sensor to obtain angular positions of the output shaft;
operating the electrical motor as the incremental sensor to determine angular positions and/or a number of revolutions of the motor shaft;
calculating real angular positions of the output shaft using the angular positions and/or the number of revolutions of the motor shaft;
comparing the angular positions of the output shaft obtained by the angular position sensor and the real angular positions of the output shaft calculated using the angular positions and/or the number of revolutions of the motor shaft; and
calibrating the angular position sensor based on the comparing.

2. The method according to claim 1, comprising calibrating the angular position sensor based on the gear ratio of the gear mechanism.

3. The method according to claim 1, wherein the angular position sensor is operating to obtain an angular position of the output shaft at predetermined time periods during an operation of the electrical motor as the incremental sensor.

4. The method according to claim 1, wherein the angular position sensor is operating to obtain a plurality of angular positions of the output shaft for at least two electrical rotations and/or rollovers of the electrical motor.

5. The method according to claim 1, further comprising:
operating the electrical motor with a constant speed as the incremental sensor for at least two electrical rotations and/or rollovers of the electrical motor; and
at least one of:
detecting a maximal angular position and a minimal angular position of the output shaft; and
calculating a resolution of the angular position sensor.

6. The method according to claim 1, further comprising at least one of:
storing the angular positions of the output shaft obtained by the angular position sensor;
storing the real angular positions of the output shaft calculated using the angular positions and/or the number of revolutions of the motor shaft; and
calculating deviations between the angular positions of the output shaft obtained by the angular position sensor and the real angular positions of the output shaft calculated using the angular positions and/or the number of revolutions of the motor shaft, storing the deviations in a memory unit of the actuator, and calibrating the incremental sensor using the deviations.

7. The method according to claim 1, comprising:
spinning the electrical motor;
checking sensor values of the angular position sensor every predetermined time period until a first rollover of the electrical motor;
continuing to spin the electrical motor;
checking sensor values of the angular position sensor every predetermined time period until a second rollover of the electrical motor;
calculating deviations between sensor values of the angular position sensor and corresponding calculated positions of the output shaft using the angular positions and/or the number of revolutions of the motor shaft;
storing the deviations in a memory unit of the actuator; and
calibrating the angular position sensor using the deviations.

8. The method according to claim 1, wherein the method is executed during a regular operation of the actuator.

9. The method according to claim 1, wherein the method is executed each time the actuator is starting and/or upon a request of a user of a vehicle in which the actuator is provided.

10. A computer program product comprising instructions that, when executed by a computer, causes the computer to carry out the method of claim 1.

11. An actuator for a vehicle application comprising an angular position sensor and an electronic control unit, wherein the actuator is configured for calibrating the angular position sensor in accordance with the method of claim 1.

12. The actuator according to claim 11, wherein the electronic control unit comprises a memory unit and a control unit, wherein in the memory unit a code is stored, wherein when the code is executed by the control unit, the method is executed.

13. The actuator according to claim 12, wherein deviations between sensor values of the angular position sensor and corresponding calculated positions of the output shaft using the angular positions and/or the number of revolutions of the motor shaft are stored in the memory unit, wherein the deviations are used for calibrating the angular position sensor.
